(19) United States
(12) Patent Application Publication
(10) Pub. No.: US 2026/0056241 A1
(43) Pub. Date: Feb. 26, 2026

(54) METHOD AND APPARATUS FOR EVALUATING DEGREE OF DEGRADATION OF ACTIVE REGION OF TRANSISTOR

(71) Applicant: WAVEPIA CO., LTD., Gyeonggi-do (KR)

(72) Inventors: Sang Hun LEE, Hwaseong-si (KR); Sang Yeol LEE, Hwaseong-si (KR); Sang Su KIM, Hwaseong-si (KR)

(73) Assignee: WAVEPIA CO., LTD., Gyeonggi-do (KR)

(21) Appl. No.: 19/272,598

(22) Filed: Jul. 17, 2025

(30) Foreign Application Priority Data
Aug. 21, 2024 (KR) 10-2024-0111921

(51) Int. Cl. G01R 31/26

(52) U.S. Cl. CPC G01R 31/2607

(57) ABSTRACT

The present invention relates to a method and apparatus for evaluating the degree of degradation of an active region of a transistor. The method of evaluating the degree of degradation of the active region of the transistor includes measuring a first resistance of a resistor unit that receives heat generated in an active region of a transistor disposed on a semiconductor device, heating the semiconductor device, measuring a second resistance of the resistor unit, repeatedly performing the measuring of the first resistance, the heating of the semiconductor device and the measuring of the second resistance after a predetermined period of time, and evaluating the degree of degradation of the active region based on a plurality of measured first resistances and a plurality of measured second resistances.

### CROSS-REFERENCE TO RELATED APPLICATION

This application claims priority to and the benefit of Korean Patent Application No. 2024-0111921, filed on Aug. 21, 2024, the disclosure of which is incorporated herein by reference in its entirety.

### BACKGROUND

### 1. Field of the Invention

The present disclosure relates to a method and apparatus for evaluating the degree of degradation of an active region of a transistor, and more particularly, to a method and apparatus for evaluating the degree of degradation of an active region of a transistor of a semiconductor device.

### 2. Discussion of Related Art

Recently, as technology has developed in fields such as electric vehicles, autonomous vehicles, wireless communication including 5G or 6G, satellite communication, and high-resolution radar, semiconductor devices used in these fields have also been developed to enable high-speed operation and high output. In order to improve the operating speed and output of the semiconductor device, a transistor disposed in the semiconductor device is switched at a higher speed, and a larger current flows in the active region of the transistor. In this process, the power consumed by the semiconductor device increases, and accordingly, the heat generation of the semiconductor device also increases.

When the heat generation of the semiconductor device increases, various parts constituting the semiconductor device may be degraded due to stress caused by excessive temperature changes. For example, cracks may occur in each layer constituting the semiconductor device, or cracks may occur between each layer. As a result, the lifespan of the semiconductor device may be shortened.

In particular, the degradation may occur prominently in the part of the semiconductor device where the temperature is highest, that is, the part where the active region of the transistor is generated. As the degradation of the active region progresses, the switching performance of the transistor may be degraded as the electron mobility decreases, and as the leakage current increases, a greater temperature increase may occur. Accordingly, as the degradation of the semiconductor device progresses, the performance and lifespan of the semiconductor device decrease rapidly.

In order to evaluate the degree of degradation of semiconductor devices, various technologies have been developed to measure the temperature of semiconductor devices. However, even when the temperature of semiconductor devices is measured, it is difficult to accurately evaluate the degree of degradation of the semiconductor devices using only the temperature. Even when the degree of degradation of semiconductor devices is small, the temperature may be high simply because the temperature is high or the usage time is long.

In addition, since the active region with the highest temperature in a semiconductor device is located inside the semiconductor device, the temperature can only be measured indirectly. Therefore, it is difficult to accurately measure the temperature of the active region of the semiconductor device, so the degree of degradation of the active region cannot be accurately evaluated using conventional techniques.

In addition, the active region is a region where electrons move and is directly related to the RF performance of the semiconductor device. Accordingly, when the temperature of the active region is measured by measuring temperature-sensitive electrical parameters (TSEPs) according to the conventional techniques, it may affect the RF performance of the semiconductor device.

That is, since the conventional techniques cannot accurately evaluate the degree of degradation of the active region, there is a problem that the performance and lifespan of the semiconductor device cannot be accurately evaluated, or the RF performance of the semiconductor device is degraded when measuring the temperature of the active region.

Accordingly, there is an urgent need for a technique that can accurately evaluate the degradation of the active region without deteriorating the RF performance of the semiconductor device.

Meanwhile, the above-mentioned background art is technical information that the inventor possessed for the purpose of derivation of the present invention or acquired during the derivation of the present invention, and cannot necessarily be said to be a known technique disclosed to the general public before the filing of the present invention.

### RELATED ART LITERATURE

### Patent Literature

(Patent literature 1) European Patent Publication No. EP 3598505 (Feb. 15, 2023)

### SUMMARY OF THE INVENTION

The present invention is directed to provide a method and apparatus for accurately evaluating the degree of degradation of an active region without degrading the RF performance of a transistor by calculating the resistance change rate of the active region using the resistance of a resistor unit that receives heat of the active region.

The present invention is also directed to provide a method and apparatus for accurately evaluating the degree of degradation of an active region without being affected by various characteristics of different semiconductor devices by calculating the resistance change rate every time a predetermined period of time passes and dividing the calculated resistance change rates obtained at different times.

The present invention is also directed to provide a method and apparatus for accurately evaluating the degree of degradation of an active region of a transistor, which can estimate the temperature of the active region without degrading the RF performance of the transistor while the transistor is operating, by obtaining the relationship between the temperature and resistance of the resistor unit in advance before the transistor operates.

The present invention is also directed to provide a method and apparatus for accurately evaluating the degree of degradation of an active region of a transistor, which can efficiently prevent the failure of a semiconductor device by obtaining the degree of degradation of the active region and a temperature estimation value of the active region together.

The problems of the present invention are not limited to the problems mentioned above, and other problems that are not mentioned will be clearly understood by those skilled in the art from the description below.

According to an aspect of the present invention, there is provided a method of evaluating the degree of degradation of an active region of a transistor, which includes: measuring a first resistance of a resistor unit that receives heat generated in an active region of a transistor disposed on a semiconductor device; heating the semiconductor device; measuring a second resistance of the resistor unit; repeatedly performing the measuring of the first resistance, the heating of the semiconductor device, and the measuring of the second resistance after a predetermined period of time has elapsed; and evaluating the degree of degradation of the active region based on a plurality of measured first resistances and a plurality of measured second resistances.

According to an embodiment, the measuring of the first resistance, the heating of the semiconductor device, the measuring of the second resistance, the repeatedly performing, and the evaluating of the degree of degradation of the active region may be performed while the transistor is operating.

According to an embodiment, the evaluating of the degree of degradation of the active region may include: obtaining a first resistance change rate before the predetermined period of time has elapsed; obtaining a second resistance change rate after the predetermined period of time has elapsed; and comparing a value obtained by dividing the second resistance change rate by the first resistance change rate with a predetermined threshold value.

According to an embodiment, the first resistance change rate may be a value obtained by dividing a difference between the first resistance and the second resistance measured before the predetermined period of time has elapsed by first power used to heat the semiconductor, and the second resistance change rate may be a value obtained by dividing a difference between the first resistance and the second resistance measured after the predetermined period of time has elapsed by second power used to heat the semiconductor.

According to an embodiment, the heating of the semiconductor device may include applying an AC signal to a gate electrode of the transistor to heat the active region, and a magnitude of a voltage of the AC signal may be smaller than a magnitude of a threshold voltage that operates the transistor.

According to an embodiment, the method of evaluating the degree of degradation of the active region of the transistor may further include, before the measuring of the first resistance: continuously heating the semiconductor device using an external heating device before the transistor operates; measuring a temperature value and a resistance value of the resistor unit at predetermined intervals while the semiconductor device is continuously heated; and estimating the temperature of the active region based on a plurality of temperature values and a plurality of resistance values of the resistor unit while the transistor is operating.

According to an embodiment, the estimating of the temperature of the active region may include: calculating each of a plurality of temperature estimation values for the active region by adding an offset to each of the plurality of temperature values; obtaining a relationship between the resistance value of the resistor unit and the temperature estimation value for the active region based on the plurality of resistance values and the plurality of temperature estimation values; and estimating the temperature of the active region using the relationship while the transistor is operating, wherein the offset may be determined according to a distance between the resistor unit and the active region.

According to another aspect of the present invention, there is provided an apparatus for evaluating the degree of degradation of an active region of a transistor, which includes: a heating unit configured to heat a semiconductor device; a measuring unit configured to measure a resistance value of a resistor unit that receives heat generated in an active region of a transistor disposed on the semiconductor device; a memory configured to store at least one instruction; and a processor connected to the heating unit, the measuring unit, and the memory to transmit and receive electrical signals and configured to execute the at least one instruction, wherein the measuring unit may measure a first resistance of the resistor unit, measure a second resistance of the resistor unit after the semiconductor device is heated by the heating unit, and repeatedly perform the measuring of the first resistance and the second resistance after a predetermined period of time has elapsed, and the processor may evaluate the degree of degradation of the active region based on a plurality of measured first resistances and a plurality of measured second resistances.

According to an embodiment, the measuring of the first resistance by the measuring unit, the heating of the semiconductor device by the heating unit, the measuring of the second resistance by the resistor unit, and the evaluating of the degree of degradation of the active region by the processor may be performed while the transistor is operating.

According to an embodiment, the processor may obtain a first resistance change rate before the predetermined period of time has elapsed, obtain a second resistance change rate after the predetermined period of time has elapsed, and compare a value obtained by dividing the second resistance change rate by the first resistance change rate with a predetermined threshold value.

According to an embodiment, the first resistance change rate may be a value obtained by dividing a difference between the first resistance and the second resistance measured before the predetermined period of time has elapsed by first power used to heat the semiconductor, and the second resistance change rate may be a value obtained by dividing a difference between the first resistance and the second resistance measured after the predetermined period of time has elapsed by second power used to heat the semiconductor.

According to an embodiment, the heating unit may include an AC signal generating unit, the AC signal generating unit may apply an AC signal to a gate electrode of the transistor to heat the active region, and a magnitude of a voltage of the AC signal may be smaller than a magnitude of a threshold voltage that operates the transistor.

According to an embodiment, the processor may continuously heat the semiconductor device using an external heating device before the transistor operates, the measuring unit may measure a temperature value and a resistance value of the resistor unit at predetermined intervals while the semiconductor device is continuously heated, and the processor may estimate a temperature of the active region based on a plurality of temperature values and a plurality of resistance values of the resistor unit while the transistor is operating.

According to an embodiment, the processor may calculate each of a plurality of temperature estimation values for the active region by adding an offset to each of the plurality of temperature values, obtain a relationship between the resistance value of the resistor unit and the temperature estimation value for the active region based on the plurality of resistance values and the plurality of temperature estimation values, and estimate the temperature of the active region using the relationship while the transistor is operating, wherein the offset may be determined according to a distance between the resistor unit and the active region.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a block diagram illustrating an apparatus for evaluating the degree of degradation of an active region of a transistor according to an embodiment of the present disclosure;

FIG. 2 is a cross-sectional view of a semiconductor device according to an embodiment of the present disclosure;

FIG. 3 is a flowchart illustrating a method of evaluating the degree of degradation of an active region of a transistor according to an embodiment of the present disclosure;

FIG. 4 is a flowchart specifically illustrating the evaluating of the degree of degradation of an active region according to another embodiment of the present disclosure;

FIG. 5 is a diagram illustrating a table for evaluating the degree of degradation of an active region according to another embodiment of the present disclosure;

FIG. 6 is a block diagram illustrating an apparatus for evaluating the degree of degradation of an active region of a transistor according to another embodiment of the present disclosure;

FIG. 7 is a flowchart illustrating a method of evaluating the degree of degradation of an active region of a transistor according to another embodiment of the present disclosure;

FIG. 8 is a diagram illustrating a semiconductor device that is heated by a processor using an external heating device according to another embodiment of the present disclosure;

FIG. 9 is a flowchart illustrating a method of measuring a temperature value and a resistance value of a resistor unit by heating a semiconductor device to estimate the temperature of an active region according to another embodiment of the present disclosure;

FIG. 10 is a flowchart specifically illustrating the estimating of the temperature of an active region according to another embodiment of the present disclosure;

FIG. 11 is a table illustrating the estimating of the temperature of an active region according to another embodiment of the present disclosure; and

FIG. 12 is a graph illustrating a relationship between a resistance value of a resistor unit and a temperature estimation value of an active region according to another embodiment of the present disclosure as a trend line.

### DETAILED DESCRIPTION OF EXEMPLARY EMBODIMENTS

Advantages and features of the present invention and methods for achieving them will be made clear from embodiments described in detail below with reference to the accompanying drawings. However, the present invention may be embodied in many different forms and should not be construed as being limited to the embodiments set forth herein. Rather, these embodiments are provided so that this disclosure will be thorough and complete and will fully convey the scope of the present invention to those of ordinary skill in the technical field to which the present invention pertains. That is, the present invention is defined only by the scope of the claims.

The shapes, sizes, ratios, angles, numbers, etc., disclosed in the drawings for explaining the embodiments in the present specification are exemplary, and the embodiments of the present specification are not limited to the illustrated points. Like reference numerals refer to like elements throughout the specification. In addition, in describing the embodiment, when it is determined that a detailed description of a related known technology may unnecessarily obscure the gist of the embodiment, the detailed description thereof will be omitted. When the terms “include,” “have,” “consist,” “comprise,” and the like are used herein, it should be understood that other parts or elements may be added unless “only” is used. When an element is expressed in the singular, it may be understood to include the plural unless specifically stated otherwise.

In interpreting components, even when there is no separate explicit description, it is interpreted to include an error range. For example, unless there is a separate explicit description, the meaning of ‘same’ does not mean perfectly the same, but means ‘substantially the same’ with an error range that a person of ordinary skill in the art can easily experience when practicing the present disclosure.

Although the terms “first,” “second,” and the like. are used to describe various components, these components are not limited by these terms. These terms are only used to distinguish one component from another. Accordingly, a first component mentioned below may also be a second component within the technical concept of the present disclosure.

Unless otherwise specified, the same reference numerals refer to the same components throughout the specification.

The features of each of the various embodiments of the present disclosure can be partially or fully combined or combined with each other, and as can be fully understood by those skilled in the art, various technical connections and operations are possible, and each embodiment can be implemented independently of each other or can be implemented together in a related relationship.

In the present disclosure, when multiple components are connected, it should be understood that each component is not only directly connected to each other, but also indirectly connected. Accordingly, when multiple components are connected to each other, another component may be connected between the multiple components.

In describing multiple embodiments of the present disclosure, when some components of an embodiment are substantially the same or correspond to some components of another embodiment described above, the description of the components may be omitted for the sake of a clear and concise description of the present disclosure. In addition, when some components have a symmetrical structure with another component, for example, an axial symmetry or a rotational symmetry structure, and both components are substantially the same except for different directions or positions, the description of the components may be omitted for the sake of a clear and concise description of the present disclosure, unless it is necessary to specify the present invention.

Hereinafter, the present invention will be described in detail with reference to the accompanying drawings.

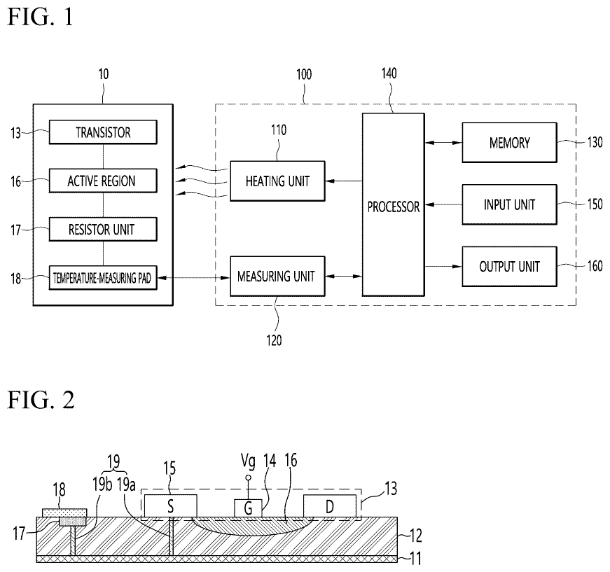

FIG. 1 is a block diagram illustrating an apparatus for evaluating the degree of degradation of an active region of a transistor according to an embodiment of the present disclosure.

First, referring to FIG. 1, an apparatus 100 for evaluating the degree of degradation of an active region of a transistor includes a heating unit 110, a measuring unit 120, a memory 130, and a processor 140. In addition, the apparatus 100 may further include an input unit 150 and an output unit 160.

Referring to FIG. 1, the heating unit 110 heats a semiconductor device 10. There may be various ways in which the heating unit 110 heats the semiconductor device 10. For example, the heating unit 110 may directly conduct heat to the semiconductor device 10 or transmit signals having various frequencies and waveforms to the semiconductor device 10 to increase the temperature of the semiconductor device 10.

A point that the heating unit 110 heats may vary. For example, the heating unit 110 may heat the entire package including the semiconductor device 10, heat only a die on which a transistor 13 is placed, or heat the entire area of the transistor 13. In addition, the apparatus 100 may heat only the active region 16 generated by the operation of the transistor 13. In this case, the apparatus 100 may apply a separate operation signal to the transistor 13 to operate the transistor 13.

Referring to FIG. 1, the measuring unit 120 measures the resistance of the resistor unit 17 of the semiconductor device 10. Specifically, the measuring unit 120 may measure the resistance of the resistor unit 17 using signals output from the resistor unit 17 according to Ohm's law.

The measuring unit 120 may apply electrical signals to the resistor unit 17. In this case, the measuring unit 120 may include a signal input unit (not shown). The signal input unit (not shown) may apply electrical signals to the resistor unit 17 using various methods. For example, the signal input unit (not shown) may apply electrical signals to a temperature-measuring pad 18 as illustrated in FIG. 1, and the resistor unit 17 may receive the electrical signals through the temperature-measuring pad 18. In some cases, the signal input unit (not shown) may apply electrical signals to the resistor unit 17 using another pad.

The measuring unit 120 may not include a signal input unit. In this case, an electrical signal that does not originate from the measuring unit 120 may be input to the resistor unit 17. For example, the resistor unit 17 may receive a low leakage current flowing inside the semiconductor device 10.

The measuring unit 120 may include at least one probe (not shown) that receives a signal generated from the resistance of the resistor unit 17 in a wired or wireless manner. For example, the measuring unit 120 may include two probes (not shown). In this case, one of the two probes (not shown) may be grounded. In some cases, there may be only a single probe (not shown) included in the measuring unit 120. In this case, the resistor unit 17 may be connected to a ground electrode. In addition, the probe (not shown) included in the measuring unit 120 may also perform the role of the signal input unit described above.

Referring to FIG. 1, the memory 130 includes at least one instruction executed by the processor 140. For example, the memory 130 may include an instruction for causing the heating unit 110 to heat the semiconductor device 10 and an instruction for causing the measuring unit 120 to measure the resistance of the resistor unit 17.

In addition, the memory 130 may store various types of data or parameters transmitted by the processor 140. For example, the memory 130 may store a time interval during which the heating unit 110 heats the semiconductor device 10, resistance values measured by the measuring unit 120, threshold values for evaluating the degree of degradation of the active region 16, and an offset for calculating a temperature estimation value in the active region 16.

In addition, the memory 130 may store various relationships calculated by the processor 140. For example, the memory 130 may store an equation for calculating a resistance change rate and a relationship between the resistance value of the resistor unit 17 and the temperature estimation value for the active region 16.

In addition, although FIG. 1 illustrates one memory 130, the number of memories 130 is not limited thereto. For example, a plurality of memories 130 may be provided. In this case, each memory 130 may store various types of data in a distributed manner according to the type, acquisition time, utilization stage, or data size of the data.

Referring to FIG. 1, the processor 140 may be connected to the heating unit 110 and the measuring unit 120 to transmit and receive electrical signals and control the heating unit 110 and the measuring unit 120. For example, the processor 140 may transmit control signals to the heating unit 110 so that the heating unit 110 heats the semiconductor device 10, and transmit control signals so that the measuring unit 120 measures the resistance of the resistor unit 17.

In addition, the processor 140 may perform various operations using data received from the heating unit 110, the measuring unit 120, and the memory 130. For example, the processor 140 may calculate the resistance change rate of the active region 16 using a difference value of the resistance values of the resistor unit 17, and compare the resistance change rate with a threshold value stored in the memory 130 to evaluate the degree of degradation of the active region 16. In addition, the processor 140 may derive a relationship between the resistance value of the resistor unit 17 and the temperature estimation value for the active region 16.

In addition, the processor 140 may be connected to the memory 130 to transmit and receive electrical signals, and transmit, to the memory 130, data acquired by the heating unit 110 and the measuring unit 120 or data and equations acquired through calculations.

Referring to FIG. 1, the input unit 150 may transmit data input by the user to the processor 140. For example, the input unit 150 may receive, from the user, information such as a time point when the heating unit 110 heats the semiconductor device 10, a threshold value for evaluating the degree of degradation of the active region 16, or a time point when the resistance value of the resistor unit 17 is measured, and transmit the received information to the processor 140.

Referring to FIG. 1, the output unit 160 may receive various types of data from the processor 140 and output the received data in various ways. For example, the output unit 160 may be a display panel. In this case, the data received from the processor 140 may be output as a table, and the relationship between the resistance value of the resistor unit 17 and the temperature estimation value for the active region 16 may be received from the processor 140 and visualized as a graph.

Referring to FIG. 1, the semiconductor device 10 may include the transistor 13, the active region 16 generated when the transistor 13 operates, the resistor unit 17 thermally connected to the active region 16, and the temperature-measuring pad 18 electrically connected to the resistor unit 17. The semiconductor device 10 will be described in detail with reference to FIG. 2.

FIG. 2 is a cross-sectional view of a semiconductor device according to an embodiment of the present disclosure.

Referring to FIG. 2, the semiconductor device 10 may include a lower metal layer 11, a substrate 12 disposed on the lower metal layer 11, a transistor 13 disposed on the substrate 12, a resistor unit 17 disposed in a layer where an active region 16 is generated when the transistor 13 operates, a temperature-measuring pad 18 electrically connected to the resistor unit 17, and a plurality of vias 19 including a thermally conductive material.

The semiconductor device 10 may be a power semiconductor used to handle high power, a high voltage, and a high current. Specifically, the semiconductor device 10 may include a power semiconductor in which a plurality of semiconductor materials are heterojunctioned. For example, the semiconductor device 10 may include a power semiconductor in which a plurality of semiconductor materials having different energy band gaps, such as gallium nitride (GaN) and aluminum gallium nitride (AlGaN), are heterojunctioned. However, the type of semiconductor device 10 is not limited thereto. For example, the semiconductor device 10 may be a logic semiconductor designed for digital signal processing and may also be a memory semiconductor used to store and retrieve data.

Referring to FIG. 2, the lower metal layer 11 may be disposed at the bottom of the semiconductor device 10. The lower metal layer 11 may include a metal material. In addition, the lower metal layer 11 may be grounded. In this case, the lower metal layer 11 may function as a ground electrode.

Referring to FIG. 2, the substrate 12 may be disposed directly on the lower metal layer 11. In FIG. 2, the substrate 12 is illustrated as one layer, but the number of layers constituting the substrate 12 may vary. For example, the substrate 12 may include at least one of a body layer for mechanical support of the entire structure, a buffer layer for stress relief, a drift layer for a voltage drop when a current flows, an epitaxial layer for controlling electrical characteristics of an apparatus, and a channel layer in which the active region 16 of the transistor 13 is generated.

The substrate 12 may include a semiconductor material. That is, the substrate 12 may be made of at least one semiconductor material. For example, the substrate 12 may be made of one semiconductor material or include a compound semiconductor material composed of two or more different elements. In this case, the substrate 12 may include a material such as gallium arsenide (GaAs), silicon carbide (SIC), or gallium nitride (GaN).

In particular, when the channel layer of the substrate 12 includes GaN, the semiconductor device 10 may enable fast switching due to high electron mobility, high power processing due to high electric field strength and thermal conductivity, and high temperature operation due to high thermal stability. A high-speed, high-output, and high-performance semiconductor device may be manufactured, and the heat generation problem occurring in such a semiconductor device may be mitigated through various embodiments of the present invention.

Referring to FIG. 2, the transistor 13 may be disposed on the substrate 12. The transistor 13 may include a gate electrode 14 (G), a source electrode 15 (S), and a drain electrode (D). The source electrode 15 and the drain electrode may be spaced apart from each other with the gate electrode 14 positioned therebetween. In addition, the gate electrode 14, the source electrode 15, and the drain electrode may all be disposed on one side of the substrate 12.

The transistor 13 may be a high electron mobility transistor (HEMT). In this case, since the transistor 13 provides high-speed switching performance and high current density, the semiconductor device 10 may exhibit excellent performance in power amplification and high-frequency applications. However, the type of transistor 13 is not limited thereto. For example, the transistor 13 may be a junction FET (JFET), a MOSFET, or a GaN FET. In particular, an active region 16 of the transistor 13 is composed of the above-described GaN, thereby providing high-speed switching performance and high current density, and reducing the heat generation of the semiconductor device 10 through various embodiments of the present invention.

Referring to FIG. 2, an active region 16, i.e., a channel, may be formed between the lower portion of the gate electrode 14 and the source electrode 15 and the drain electrode. Specifically, in a case in which a control signal Vg is applied to the gate electrode 14, when the voltage of the control signal is high, an active region is generated in the channel layer of the substrate 12, allowing a current to flow between the source electrode 15 and the drain electrode. Conversely, when the voltage of the control signal is low, the active region disappear, and a current flow between the source electrode 15 and the drain electrode is blocked. In addition, depending on the magnitude of the voltage of the control signal applied to the gate electrode 14, the degree of amplification of the signal output from the drain electrode may be determined.

A significant amount of heat may be generated in the active region 16 due to the flow of a current. In particular, when the transistor 13 operates at high power and high frequency, the heat generated in the active region 16 may further increase. The heat generated in this way may accumulate in or around the active region 16. Therefore, when the transistor 13 is operating, the hottest region in the semiconductor device 10 may be the active region 16. In addition, when the channel layer includes a material with high thermal conductivity such as GaN, the heat generated in the active region 16 may spread to the entire channel layer where the active region 16 is generated.

Referring to FIG. 2, the resistor unit 17 may be disposed in the layer where the active region 16 is generated when the transistor 13 operates. In addition, the resistor unit 17 may be disposed to be spaced a predetermined distance from the transistor 13 and the active region 16. Accordingly, when the measuring unit 120 measures the resistance of the resistor unit 17, the RF performance of the transistor 13 may not be degraded.

Referring to FIG. 2, the upper side of the resistor unit 17 may be in direct contact with the temperature-measuring pad 18. Specifically, the upper surface of the resistor unit 17 is exposed on the upper surface of the substrate 12 and may be in direct contact with the temperature-measuring pad 18. However, the position of the upper side of the resistor unit 17 is not limited thereto. For example, the resistor unit 17 may be disposed inside the substrate 12 so as to be covered by the material constituting the substrate 12. In this case, the resistor unit 17 and the temperature-measuring pad 18 may be electrically connected to each other through a via including an electrically conductive material.

Meanwhile, the shape of the resistor unit 17 may vary. For example, the resistor unit 17 may have a protruding shape, i.e., a mesa shape, through an etching process, or may have a thin film shape formed through a deposition process.

Referring to FIG. 2, the resistor unit 17 may be thermally connected to the active region 16. In particular, when the layer in which the active region 16 is formed includes a material with high thermal conductivity, such as GaN, the resistor unit 17 may effectively receive the heat generated in the active region 16 through the channel layer. Accordingly, the temperature of the resistor unit 17 may vary depending on the temperature of the active region 16.

However, since the material located between the resistor unit 17 and the active region 16 has thermal resistance, the heat generated in the active region 16 may not be fully transferred to the resistor unit 17. Accordingly, as the distance between the resistor unit 17 and the active region 16 increases, the temperature of the resistor unit 17 may gradually decrease compared to the temperature of the active region 16.

Meanwhile, the resistor unit 17 may have a positive temperature coefficient (PTC). That is, as the temperature of the resistor unit 17 increases, the resistance value of the resistor unit 17 may also increase.

In addition, the resistor unit 17 may have a linear temperature coefficient of resistance (TC). That is, the resistance value of the resistor unit 17 may be proportional to the temperature of the resistor unit 17.

Referring to FIG. 2, the temperature-measuring pad 18 may be electrically connected to the resistor unit 17 directly or through vias. The temperature-measuring pad 18 may function as a contact point for the measuring unit 120 to receive an electrical signal generated from the resistor unit 17 or for the measuring unit 120 to transmit a current to the resistor unit 17. For this purpose, the temperature-measuring pad 18 may include a metal material such as aluminum, copper, or gold, or a conductive alloy material.

Referring to FIG. 2, vias 19 may have a shape that vertically passes through the substrate 12. In addition, the vias 19 may have a shape in which a metal material is deposited inside a hole that vertically passes through the substrate 12. That is, the via 19 may be a through silicon via (TSV).

The via 19 may include a first via 19a and a second via 19b. Specifically, the first via 19a may vertically pass through between the lower surface of the source electrode 15 and the upper surface of the lower metal layer 11. Accordingly, the source electrode 15 may be electrically connected to the lower metal layer 11. As described above, when the lower metal layer 11 is grounded, the source electrode 15 may also be grounded. In this case, the semiconductor device 10 may not have a pad for applying a signal to the source electrode 15.

The second via 19b may vertically pass through between the lower surface of the resistor unit 17 and the upper surface of the lower metal layer 11. Accordingly, the resistor unit 17 may be electrically connected to the lower metal layer 11. As described above, when the lower metal layer 11 is grounded, the resistor unit 17 may also be grounded. In this case, since a grounded probe is not required to measure the resistance of the resistor unit 17, the measuring unit 120 may measure the resistance of the resistor unit 17 by contacting only a single probe to the temperature-measuring pad 18.

Meanwhile, at least some of the plurality of vias 19 may include a thermally conductive material. For example, the first via 19a may include a thermally conductive material. In this case, the heat generated in the active region 16 may be transferred to the lower metal layer 11 through the first via 19a disposed adjacent to the active region 16 and released to the lower part of the semiconductor device 10. Accordingly, the heat dissipation performance of the semiconductor device 10 may be improved.

In addition, the second via 19b may also include a thermally conductive material. In this case, the heat generated in the source electrode 15 and transferred to the lower metal layer 11 may be transferred to the resistor unit 17 through the second via 19b. Accordingly, the resistor unit 17 may receive the heat of the active region 16 through the lower metal layer 11 and the vias 19 while receiving the heat of the active region 16 through the material constituting the layer in which the active region 16 is generated. Accordingly, the temperature of the resistor unit 17 may closely approximate the temperature of the active region 16.

Meanwhile, when the resistor unit 17 and the temperature-measuring pad 18 do not directly contact each other as described above, but are electrically connected to each other through a via (not shown), the via (not shown) connecting the resistor unit 17 and the temperature-measuring pad 18 may not include a thermally conductive material. This is because when the via (not shown) connecting the resistor unit 17 and the temperature-measuring pad 18 includes a thermally conductive material, the characteristics of the temperature-measuring pad 18 may change due to the heat of the resistor unit 17, making it difficult for the measuring unit 120 to measure the temperature of the resistor unit 17 under consistent conditions.

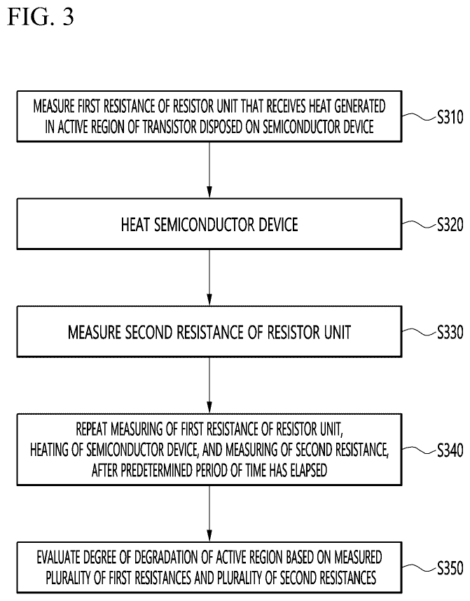

FIG. 3 is a flowchart illustrating a method of evaluating the degree of degradation of an active region of a transistor according to an embodiment of the present disclosure.

Referring to FIGS. 1 to 3, first, in operation S310, the measuring unit 120 measures a first resistance of the resistor unit 17. Here, the resistor unit 17 receives heat generated in the active region 16 of the transistor 13 disposed on the semiconductor device 10.

A time point when the measuring unit 120 measures the first resistance may be before the transistor 13 operates or may be during the operation of the transistor 13. The time point when the measuring unit 120 measures the first resistance while the transistor 13 is operating may be a time point when the transistor 13 operates at a stable temperature. Here, the stable temperature may refer to a temperature at which the transistor 13 is not overheated due to switching overload of the transistor 13 or intervention from outside the semiconductor device 10, and the transistor 13 can operate under stable thermal conditions within a normal temperature range.

Referring to FIGS. 1 to 3, the heating unit 110 heats the semiconductor device 10 in operation S320, and the measuring unit 120 measures the second resistance of the resistor unit 17 of the heated semiconductor device 10 in operation S330. Here, the second resistance may be higher than the first resistance.

Referring to FIGS. 1 to 3, in operation S340, after a predetermined period of time has elapsed, the measuring unit 120 repeats operations of measuring the first resistance of the resistor unit 17 in a state where the heating unit 110 does not heat the semiconductor device 10 and measuring the second resistance of the resistor unit 17 in a state where the heating unit 110 heats the semiconductor device 10. At this time, the number of times these operations are repeated may not be limited. For example, the heating unit 110 and the measuring unit 120 may continue to repeatedly perform the operations until the processor 140 evaluates that the performance degradation of the semiconductor device 10 is severe due to excessive degradation of the semiconductor device 10. Accordingly, the number of a plurality of first resistances and the number of a plurality of second resistances measured by the measuring unit 120 may each be three or more.

Here, the predetermined period of time is a period set in advance by the user and may be a period of time for comparing the resistance change rates of the active region 16 to evaluate the degradation of the active region 16.

Referring to FIGS. 1 to 3, in operation S350, the processor 140 may evaluate the degree of degradation of the active region 16 based on the measured plurality of first resistances and plurality of second resistances. The processor 140 may evaluate the degree of degradation of the active region 16 at various levels. For example, the processor 140 may evaluate the degree of degradation of the active region 16 as “good” when the degradation of the active region 16 has hardly progressed, “normal” when the degradation of the active region 16 has progressed to some extent but the performance degradation of the semiconductor device 10 is low and no failure is expected, and “severe” when the degradation of the active region 16 has progressed severely and the performance of the semiconductor device 10 is excessively degraded or a failure is expected soon.

As described above, when the resistor unit 17 has a linear temperature coefficient, the first resistance and the second resistance measured by the measuring unit 120 may have a linear relationship with the temperature value of the resistor unit 17. In addition, since the resistor unit 17 receives the heat of the active region 16 through the material constituting the layer in which the active region 16 is generated, the lower metal layer 11, and the via 19, the temperature of the active region 16 may be maximally reflected in the temperature of the resistor unit 17. Accordingly, the apparatus 100 may accurately evaluate the degree of degradation of the active region 16 based on the resistance value of the resistor unit 17 without directly measuring the temperature of the active region 16 and thus without degrading the RF performance of the semiconductor device 10.

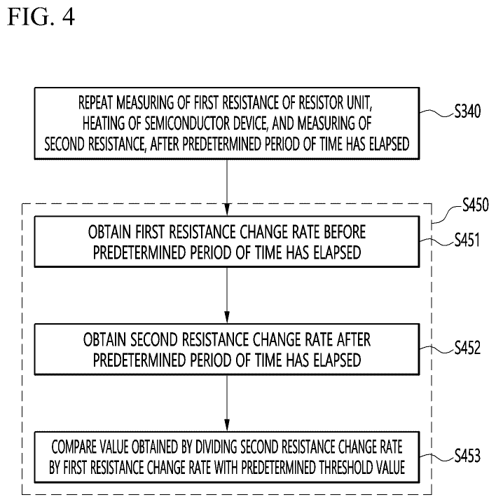

FIG. 4 is a flowchart specifically illustrating the evaluating of the degree of degradation of an active region according to another embodiment of the present disclosure.

Referring to FIG. 4, when evaluating the degree of degradation of the active region in operation S450, the processor 140 may obtain a first resistance change rate in operation S451 before a predetermined period of time has elapsed, and obtain the second resistance change rate in operation S452 after the predetermined period of time has elapsed. Here, the first resistance change rate may be a value obtained by dividing a difference between the first and second resistances measured before the predetermined period of time has elapsed by first power used to heat the semiconductor device, and the second resistance change rate may be a value obtained by dividing the difference between the first and second resistances measured after the predetermined period of time has elapsed by second power used to heat the semiconductor device. Here, the first power and the second power may be different from each other, but in some cases, they may be the same.

The resistance change rate may indicate how much the resistance changes relative to the power used for heating. Specifically, the resistance change rate can be calculated as shown in the following Equation 1. Here, Rc is a resistance change rate, ΔR is a difference between the first and second resistances, and P is the power used by the heating unit 110 to heat the semiconductor device 10.

$$Rc = \frac{Δ R}{P} \qquad [ Equation 1 ]$$

As described above, when the temperature coefficient of the resistor unit 17 is linear, ΔR is proportional to a difference between the temperature of the resistor unit 17 when the first resistance is measured and the temperature of the resistor unit 17 when the second resistance is measured. Accordingly, the resistance change rate may represent a change in temperature relative to the power used for heating.

In addition, as described above, the temperature of the resistor unit 17 may closely approximate the temperature of the active region 16. In addition, as the degradation of the active region 16 progresses, the degree to which the temperature of the active region 16 increases by the same power increases. Accordingly, the resistance change rate can be used to evaluate the degradation of the active region 16.

Referring to FIG. 4, in operation S453, the processor 140 may compare a value obtained by dividing the second resistance change rate by the first resistance change rate with a predetermined threshold value. The resistance change rate may vary depending on the characteristics of the semiconductor device 10. Specifically, the resistance change rate may vary depending on the structure and material of the channel layer in which the active region 16 is generated, or the length of the active region 16, i.e., the width of the channel. However, when the second resistance change rate is divided by the first resistance change rate, the influence of the characteristics of the semiconductor device 10 can be eliminated. Accordingly, according to the above-described embodiment, the apparatus 100 can evaluate the degree of degradation of the active region 16 that has progressed over time regardless of the characteristics of the semiconductor device 10.

When the value obtained by dividing the second resistance change rate by the first resistance change rate is 1, the processor 140 may determine that the degradation of the active region 16 has not progressed for a predetermined period of time. On the other hand, when the value obtained by dividing the second resistance change rate by the first resistance change rate exceeds 1, the processor 140 may determine that the degradation of the active region 16 has progressed over a predetermined period of time.

Here, the predetermined threshold value is a value input by the user to the processor 140 through the input unit 150 and may be a criterion for evaluating the degree of degradation of the active region 16. Therefore, when the processor 140 evaluates the degree of degradation of the active region 16 as three types, for example, “good,” “normal,” and “severe,” the number of predetermined threshold values set in advance may be two, that is, a value that distinguishes between “good” and “normal,” and a value that distinguishes between “normal” and “severe.” Alternatively, the degree of degradation of the active region 16 may be expressed in a numerical form.

According to the above-described embodiment, the apparatus 100 may evaluate the degradation of the active region 16 that progresses over time without being affected by various characteristics of different semiconductor devices 10.

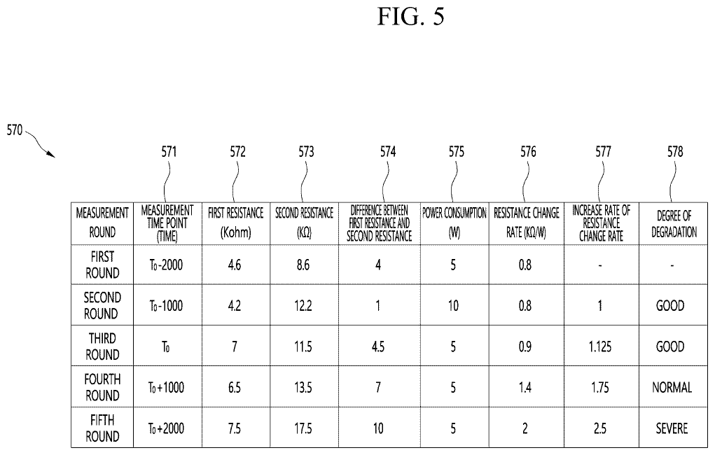

FIG. 5 is a diagram illustrating a table for evaluating the degree of degradation of an active region before a transistor operates according to another embodiment of the present disclosure.

Referring to FIG. 5, a table 570 may be generated based on data that the measuring unit 120 measures a first resistance 572 and a second resistance 573 five times and the processor 140 evaluates a degree of degradation 578 of the active region 16 at each time based on the measured information and stores the evaluated information in the memory 130.

Referring to FIG. 5, the interval between measurement points 571 for each round, i.e., a predetermined period of time in the present disclosure, is 1000 hours. In addition, To at the measurement point 571 is a time point at which the transistor 13 operates. That is, the 1st measurement and the 2^{nd} measurement are performed before the transistor 13 operates, the 3^{rd} measurement is performed at the time point the transistor 13 starts to operate at a stable temperature, and the 4^{th} measurement and the fifth measurement are performed while the transistor 13 is operating.

Referring to FIG. 5, the threshold values for evaluating the degree of degradation 578 in each round are 1.5 and 2. Accordingly, in the case in which the processor 140 evaluates the degree of degradation 578 in each round, when an increase rate 577 of the resistance change rate is less than 1.5, “good” is output, when the increase rate 577 of the resistance change rate is 1.5 or more and less than 2, “normal” is output, and when the increase rate 577 of the resistance change rate is 2 or more, “severe” is output.

Referring to FIG. 5, in the 1^{st} measurement, since the first resistance 572 is 4.6 KΩ and the second resistance 573 after the semiconductor device 10 is heated is 8.6 KΩ, a difference value 574 between the first resistance and the second resistance is 4. Since power 575 used to heat the semiconductor device 10 is 5 W, the resistance change rate 576 in the 1^{st} measurement is 0.8.

Referring to FIG. 5, in the 2^{nd} measurement, since the first resistance 572 is 4.2 KΩ and the second resistance 573 after the semiconductor device 10 is heated is 12.2 KΩ, the difference value 574 between the first resistance and the second resistance is 8. Since the power 575 used to heat the semiconductor device 10 is 10 W, the resistance change rate 576 in the 2^{nd} measurement is 0.8. In this way, even when the consumption of the power 575 is different from each other, the degree of temperature increase of the active region 16 relative to the consumption of the power 575 is the same, so the resistance change rate 576 can be used to evaluate the degree of degradation of the active region 16 regardless of the magnitude of the consumption of the power 575.

Since the resistance change rate 576 in the 1^{st} measurement and the resistance change rate 576 in the 2^{nd} measurement are the same, the increase rate 577 of the resistance change rate in the 2^{nd} measurement is 1. Since the increase rate 577 of the resistance change rate is less than 1.5, the processor 140 evaluates the degree of degradation 578 of the active region 16 in the 2^{nd} measurement as “good.”

Referring to FIG. 5, since the measurement point of the 3^{rd} measurement is T₀, that is, a time point at which the transistor 13 starts to operate at a stable temperature, the temperature of the active region 16 increases and the resistance of the resistor unit 17 increases compared to the 1^{st} measurement point and the 2^{nd} measurement point. Accordingly, the first resistance 572 in the 3^{rd} measurement is 7 KΩ2, which is higher than the first resistance 572 in the 1^{st} measurement and the 2^{nd} measurement.

In addition, since the second resistance 573 after the semiconductor device 10 is heated is 11.5 KΩ, the difference value 574 between the first resistance and the second resistance is 4.5. Since the power 575 used to heat the semiconductor device 10 is 5 W, the resistance change rate 576 in the 3^{rd} measurement is 0.9. Since the resistance change rate 576 in the 1^{st} measurement is 0.8, the increase rate 577 of the resistance change rate in the 3^{rd} measurement is 1.125. Since the increase rate 577 of the resistance change rate is less than 1.5, the processor 140 evaluates the degree of degradation 578 of the active region 16 in the 3^{rd} measurement as “good.”

Meanwhile, as the resistance change rate 576 of the previous time point used to calculate the increase rate 577 of the resistance change rate, the resistance change rate 576 of various time points may be selected. For example, the resistance change rate 576 of the initial measurement round, i.e., the 1^{st} measurement round, may be used to calculate the increase rate 577 of the resistance change rate of the 3^{rd} measurement round. In this case, compared to the initial state of the active region 16, the degree of degradation 578 of the active region 16 can be evaluated in the 3^{rd} measurement round. In some cases, the resistance change rate 576 in the previous measurement round, i.e., the 2^{nd} measurement round, can be used to calculate the increase rate 577 of the resistance change rate in the 3^{rd} measurement round. In this case, a rate at which the increase rate 577 of the resistance change rate increases as the measurement round is repeated may be confirmed. In the embodiment of the present disclosure, the increase rate 577 of the resistance change rate in the corresponding measurement round may be calculated using the resistance change rate 576 in the 1^{st} measurement round.

Referring to FIG. 5, the measurement point 571 of the 4^{th} measurement is a time point at which 1000 hours have passed from T₀. The first resistance 572 in the 4^{th} measurement is 6.5 KΩ, which is lower than the first resistance 572 in the 3^{rd} measurement. This phenomenon may be caused by various reasons. For example, it may be because the temperature at the 4^{th} measurement point 571 is higher than the temperature at the 3^{rd} measurement point 571.

In addition, since the second resistance 573 after the semiconductor device 10 is heated is 13.5 KΩ, a difference value 574 between the first resistance and the second resistance is 7. Since the power 575 used to heat the semiconductor device 10 is 5 W, the resistance change rate 576 in the 4^{th} measurement is 1.4. The resistance change rate 576 in the 1^{st} measurement is 0.8, so the increase rate 577 of the resistance change rate in the 4^{th} measurement is 1.75. Since the increase rate 577 of the resistance change rate is 1.5 or more and less than 2, the processor 140 evaluates the degree of degradation 578 of the active region 16 in the 4^{th} measurement as “normal.”

Referring to FIG. 5, the measurement point 571 of the 5^{th} measurement is a time point at which 2000 hours have passed from T₀. Since the first resistance 572 in the 5^{th} measurement is 7.5 KΩ and the second resistance 573 after the semiconductor device 10 is heated is 17.5 KΩ, the difference value 574 between the first resistance and the second resistance is 10. Since the power 575 used to heat the semiconductor device 10 is 5 W, the resistance change rate 576 in the 5^{th} measurement is 2. The resistance change rate 577 in the 1^{st} measurement is 0.8, so the increase rate 576 of the resistance change rate in the 5^{th} measurement is 2.5. Since the increase rate 577 of the resistance change rate is 2 or more, the processor 140 evaluates the degree of degradation 578 of the active region 16 in the 5^{th} measurement as “severe.”

According to the above-described embodiment, regardless of whether the measurement point 571 is before or after the transistor 13 operates, and regardless of the temperature around the semiconductor device 10 or the magnitude of the power consumption 575 at the measurement point 571, the processor 140 may independently evaluate the degree of degradation 578 of the active region 16. In addition, the processor 140 may classify the degree of degradation 578 of the active region 16 into various levels according to the severity of the degradation.

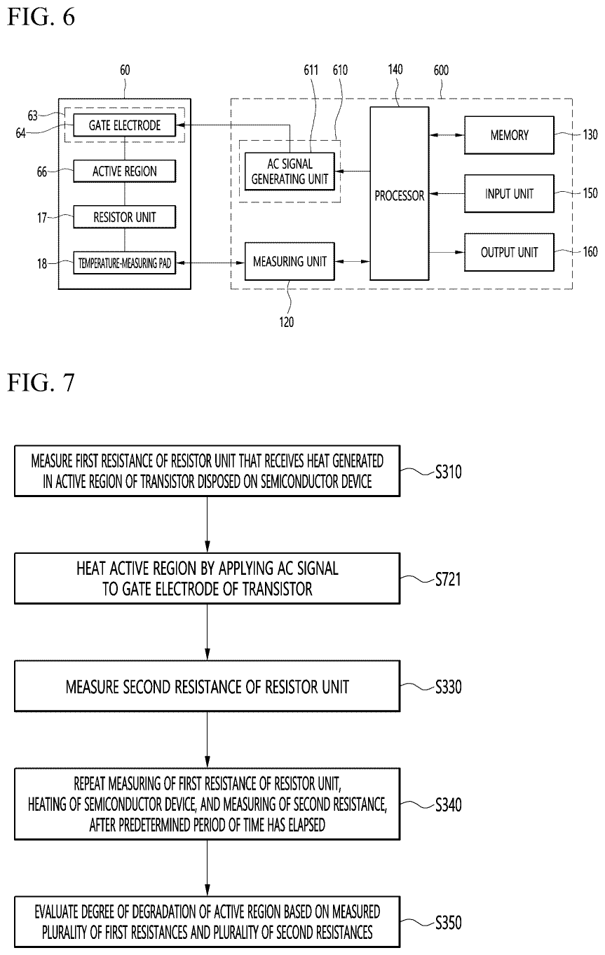

FIG. 6 is a block diagram illustrating an apparatus for evaluating the degree of degradation of an active region of a transistor according to another embodiment of the present disclosure. FIG. 7 is a flowchart illustrating a method of evaluating the degree of degradation of an active region of a transistor according to another embodiment of the present disclosure.

Referring to FIGS. 6 and 7, a heating unit 610 may include an AC signal generating unit 611. In operation S721, the AC signal generating unit 611 may heat an active region 66 by applying an AC signal to a gate electrode 64 of a transistor 63. The gate electrode 64 is directly involved in the generation or annihilation of the active region 66 and is positioned directly above the active region 66. Accordingly, when an AC signal is applied to the gate electrode 64, the energy of the AC signal, i.e., power, may be fully used to increase the temperature of the active region 66. Accordingly, the resistance change rate of the resistor unit 17 may represent a difference value between the first resistance and the second resistance compared to the power fully used to heat the active region 66.

Meanwhile, the magnitude of the voltage of the AC signal may be smaller than the magnitude of the threshold voltage that operates the transistor 63. Accordingly, even when the AC signal generating unit 611 heats the active region 66 by applying an AC signal to the gate electrode 64, the operation of the transistor 63 may not be interrupted or the RF performance of the transistor 63 may not be degraded.

Referring to FIGS. 2 and 6, when an AC signal is applied to the gate electrode 64 while the transistor 63 is operating, the AC signal may be applied to the gate electrode 64 by being superimposed on a control signal Vg or may be applied to the gate electrode 64 as a separate signal from the control signal Vg. When the AC signal is applied to the gate electrode 64 by being superimposed on the control signal Vg, the frequency of the AC signal may be much higher than the frequency of the control signal Vg.

Referring to FIGS. 5 and 6, the power amount of the AC signal applied to the gate electrode 64 at each measurement point 571 may be the same. For example, the AC signal generating unit 611 may be set in advance to apply an AC signal of the same power to the gate electrode 64 for the same time at all measurement points 571. In this case, since the consumption of the power 575 becomes the same in all rounds, the consumption of the power 575 can be eliminated when calculating the increase rate 577 of the resistance change rate. Accordingly, the increase rate 577 of the resistance change rate may be calculated directly using only the difference value 574 between the first and second resistances without having to calculate the consumption of the power 575 or the resistance change rate 576.

According to the above-described embodiment, since the power of the AC signal is entirely used to increase the temperature of the active region 66, the apparatus 100 may very precisely evaluate the degree of degradation 578 of the active region 66. In addition, the apparatus 100 may not degrade the RF performance of the transistor 63 when applying the AC signal to the gate electrode 64. In addition, the calculation process for evaluating the degree of degradation 578 of the active region 66 can be simplified.

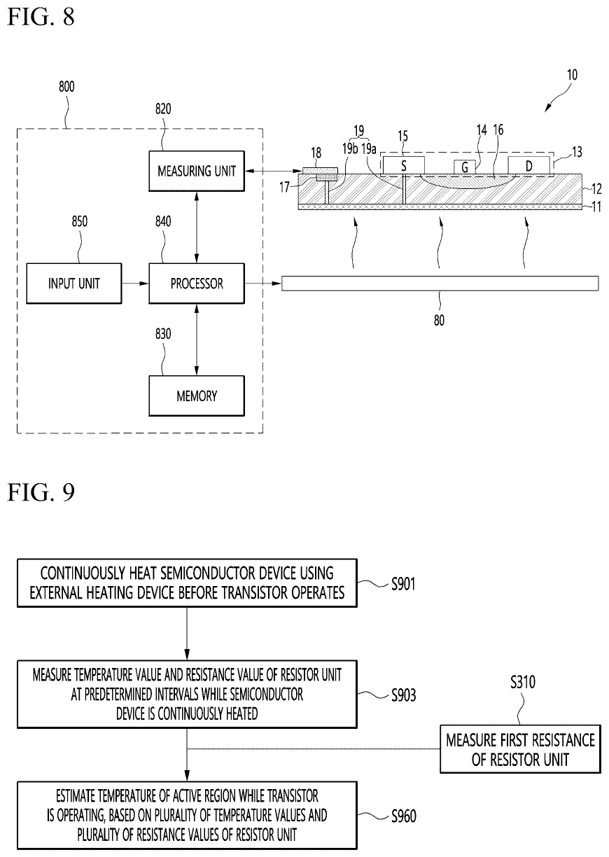

Meanwhile, according to another embodiment of the present disclosure, the apparatus 100 may obtain the temperature-resistance relationship of the resistor unit 17 before the transistor 63 operates and use this relationship to estimate the temperature of the active region 66 when the transistor 63 operates. This will be described in detail later with reference to FIGS. 8 and 9.

FIG. 8 is a diagram illustrating a semiconductor device that is heated by a processor using an external heating device according to another embodiment of the present disclosure. FIG. 9 is a flowchart illustrating a method of measuring a temperature value and a resistance value of a resistor unit by heating a semiconductor device to estimate the temperature of an active region according to another embodiment of the present disclosure.

Referring to FIGS. 8 and 9, in operation S901, a processor 840 may continuously heat the semiconductor device 10 using an external heating device 80 before the transistor 13 operates. Here, the heating device 80 is a separate device that is not included in an apparatus 800 or the semiconductor device 10. The heating device 80 may be a hot plate that heats the semiconductor device 10 placed on the upper side.

Referring to FIGS. 8 and 9, in operation S903, a measuring unit 820 may measure the temperature value and resistance value of the resistor unit 17 at predetermined intervals while the semiconductor device 10 is continuously heated. The method by which the measuring unit 820 measures the temperature value of the resistor unit 17 may vary. For example, the measuring unit 820 may derive the temperature value based on the resistance value of the resistor unit 17 and may also derive the temperature value of the resistor unit 17 directly using a contact temperature sensor or a non-contact temperature sensor.

Here, the predetermined interval is an interval input by the user to an input unit 850 and may be an interval for obtaining temperature-resistance data of the resistor unit 17. The user may set the predetermined interval based on various criteria. For example, the predetermined interval may be a constant time interval, an interval for the temperature value of the resistor unit 17, or an interval for the resistance value of the resistor unit 17 that changes as the temperature changes.

Referring to FIGS. 8 and 9, in operation S960, based on a plurality of temperature values and a plurality of resistance values of the resistor unit 17, the processor 840 may estimate the temperature of the active region 16 while the transistor is operating. That is, the processor 840 may estimate the temperature of the active region 16 based on the resistance value of the resistor unit 17 measured while the transistor 13 is operating, using the temperature-resistance relationship of the resistor unit 17 obtained before the transistor 13 operates.

According to the above-described embodiment, the apparatus 100 may estimate the temperature of the active region 16 without degrading the RF performance of the transistor 13 while the transistor 13 is operating by obtaining the temperature-resistance relationship of the resistor unit 17 in advance before the transistor 13 operates.

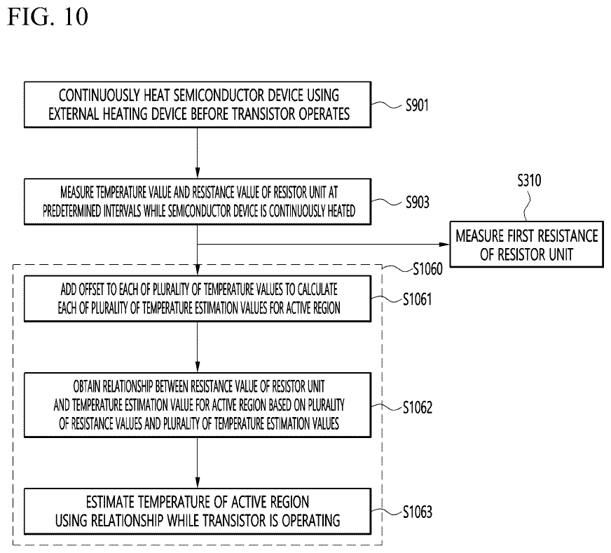

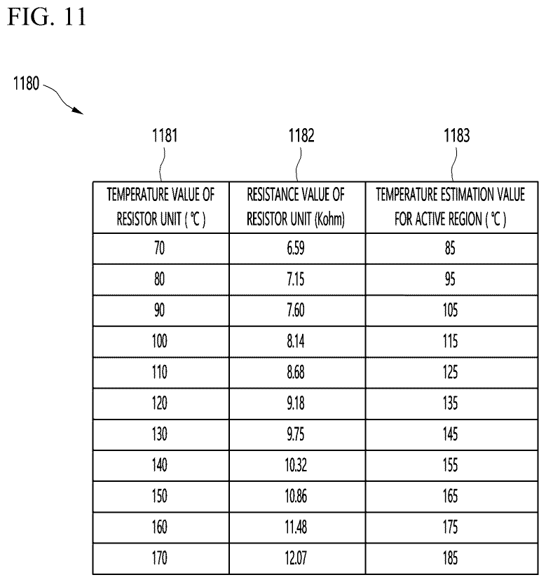

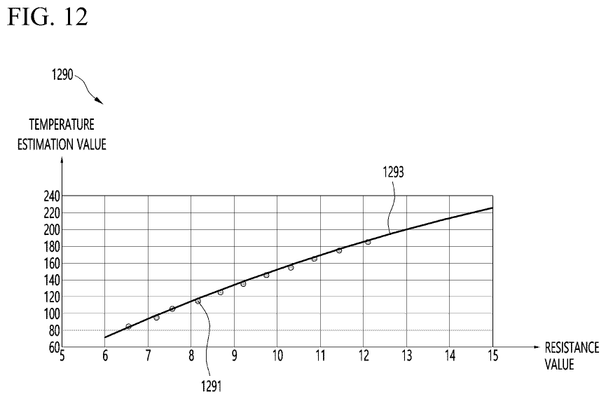

FIG. 10 is a flowchart specifically illustrating the estimating of the temperature of an active region according to another embodiment of the present disclosure. FIG. 11 is a table illustrating the estimating of the temperature of an active region according to another embodiment of the present disclosure. FIG. 12 is a graph illustrating a relationship between a resistance value of a resistor unit and a temperature estimation value of an active region according to another embodiment of the present disclosure as a trend line.

Referring to FIG. 10, when estimating the temperature of the active region 16 in operation S1060, in operation S1061, the processor 140 may first add an offset to each of the plurality of temperature values of the resistor unit 17 to calculate each of a plurality of temperature estimation values for the active region 16. Here, the offset is a value input by the user or calculated by the processor 140 and may be determined according to a distance between the resistor unit 17 and the active region 16. Accordingly, the temperature estimation value for the active region 16 may be very similar to the actual temperature of the active region 16.

Referring to FIG. 11, a table 1180 includes a temperature value 1181 of the resistor unit measured at 10° C. intervals, a resistance value 1182 of the corresponding resistor unit, and a temperature estimation value 1183 for the active region. In this embodiment, the offset is set to 15° C., and thus a temperature estimation value 1183 for the active region is calculated to be 15° C. higher than the temperature value 1181 of the resistor unit.

Referring to FIG. 10, in operation S1062, the processor 140 may obtain a relationship between the resistance value of the resistor unit 17 and the temperature estimation value for the active region 16 based on the plurality of resistance values of the resistor unit 17 and the plurality of temperature estimation values for the active region 16. Next, in operation S1063, the processor 140 may estimate the temperature of the active region 16 using this relationship while the transistor 13 is operating.

Referring to FIGS. 11 and 12, the X-axis of a graph 1290 is an axis for the resistance value 1182 of the table 1180, and the Y-axis is an axis for the temperature estimation value 1183 of the table 1180. In addition, each of the points 1291 is generated based on the data expressed in the table 1180. Based on this data, the processor 140 may generate a relationship between the resistance value of the resistor unit 17 and the temperature estimation value for the active region 16 and may also generate a trend line 1293 that appropriately expresses the distribution of the points 1291 based on the relationship. The trend line 1293 may have various types. For example, the trend line 1293 may be a linear trend line, a logarithmic trend line, or a polynomial trend line.

According to the above-described embodiment, by measuring the resistance value of the resistor unit 17 while the transistor 13 is operating, the degree of degradation of the active region 16 can be evaluated, and the temperature of the active region 16 can also be estimated. Accordingly, the apparatus 100 can efficiently prevent a failure of the semiconductor device 10 according to the degree of degradation of the active region 16. For example, the user can set a temperature threshold value according to the degree of degradation of the transistor 13. The temperature threshold value can be set to decrease as the degree of degradation of the transistor 13 becomes more severe. In addition, when the temperature estimation value of the active region 16 exceeds the temperature threshold value, the processor 140 can reduce the power input to the semiconductor device 10 until the temperature estimation value of the active region 16 becomes lower than the temperature threshold value.

In addition, when the resistor unit 17 generally does not have a linear temperature coefficient, it may be difficult to accurately estimate the temperature of the active region 16 while the transistor 13 is operating. However, the apparatus 100 can accurately estimate the temperature of the active region 16 regardless of whether the temperature coefficient of the resistor unit 17 is linear or nonlinear by obtaining the temperature-resistance relationship in advance before the transistor 13 operates.

Meanwhile, in the embodiments of the present disclosure, each block or each step may be a module, segment, or part of code that includes one or more executable instructions for executing a specific function. In addition, the blocks or steps illustrated in the drawings for explaining the above-described embodiments may function out of order. For example, two blocks or steps that are sequentially connected may be executed substantially simultaneously or may be executed in reverse order.

Furthermore, the steps of the method or algorithm described in connection with the embodiments of the present disclosure may be implemented directly in hardware, software modules, or a combination of the two, executed by a processor. The software modules may reside in a random-access memory (RAM) memory, a flash memory, a read-only memory (ROM) memory, an erasable programming ROM (EPROM) memory, an electrically EPROM (EEPROM) memory, a register, a hard disk, a removable disk, a compact disc read-only memory (CD-ROM), or any other form of recording medium or storage medium known in the art. An exemplary recording medium or storage medium is coupled to the processor such that the processor can read information from the recording medium or storage medium and write information to the recording medium or storage medium. Alternatively, the recording medium or storage medium may be integral to the processor. The processor and the recording medium or storage medium may reside within an application specific integrated circuit (ASIC). The ASIC may reside within a user terminal. Alternatively, the processor and the storage medium may reside as discrete components within the user terminal.

According to the present invention, the method and apparatus for evaluating the degree of degradation of the active region of the transistor can accurately evaluate the degree of degradation of the active region without degrading the RF performance of the transistor by calculating the resistance change rate of the active region using the resistance of the resistor unit that receives the heat of the active region.

In addition, according to the present invention, the method and apparatus for evaluating the degree of degradation of the active region of the transistor can evaluate the degree of degradation of the active region without being affected by various characteristics of different semiconductor devices by calculating the resistance change rate every time a predetermined period of time passes and dividing the resistance change rates.

In addition, according to the present invention, the method and apparatus for evaluating the degree of degradation of the active region of the transistor can estimate the temperature of the active region without degrading the RF performance of the transistor while the transistor is operating by obtaining a relationship between the temperature and resistance of the resistor unit in advance before the transistor operates.

In addition, according to the present invention, the method and apparatus for evaluating the degree of degradation of the active region of the transistor can efficiently prevent a failure of the semiconductor device by obtaining the degree of degradation of the active region along with the temperature estimation value.

Although embodiments of the present disclosure have been described in more detail with reference to the attached drawings, the present invention is not necessarily limited to these embodiments, and various modifications may be made without departing from the technical idea of the present invention. Accordingly, the embodiments of the present disclosure are not intended to limit the technical idea of the present invention, but to explain it, and the scope of the technical idea of the present invention is not limited by these embodiments. Therefore, it should be understood that the embodiments described above are exemplary in all aspects and not restrictive. The protection scope of the present invention should be interpreted by the following claims, and all technical ideas within a scope equivalent thereto should be interpreted as being included in the scope of rights of the present invention.

What is claimed is:

1. A method of evaluating the degree of degradation of an active region of a transistor, the method comprising:
measuring a first resistance of a resistor unit that receives heat generated in an active region of a transistor arranged on a semiconductor device;
heating the semiconductor device;
measuring a second resistance of the resistor unit;
repeatedly performing the measuring of the first resistance, the heating of the semiconductor device, and the measuring of the second resistance after a predetermined period of time has elapsed; and
evaluating a degree of degradation of the active region based on a plurality of measured first resistances and a plurality of measured second resistances.

2. The method of claim 1, wherein the measuring of the first resistance, the heating of the semiconductor device, the measuring of the second resistance, the repeatedly performing, and the evaluating of the degree of degradation of the active region are performed while the transistor is operating.

3. The method of claim 2, wherein the evaluating of the degree of degradation of the active region includes:
obtaining a first resistance change rate before the predetermined period of time has elapsed;
obtaining a second resistance change rate after the predetermined period of time has elapsed; and
comparing a value obtained by dividing the second resistance change rate by the first resistance change rate with a predetermined threshold value.

4. The method of claim 3, wherein:
the first resistance change rate is a value obtained by dividing a difference between the first resistance and the second resistance measured before the predetermined period of time has elapsed by first power used to heat the semiconductor; and
the second resistance change rate is a value obtained by dividing a difference between the first resistance and the second resistance measured after the predetermined period of time has elapsed by second power used to heat the semiconductor.

5. The method of claim 2, wherein the heating of the semiconductor device includes applying an AC signal to a gate electrode of the transistor to heat the active region, and a magnitude of a voltage of the AC signal is smaller than a magnitude of a threshold voltage that operates the transistor.

6. The method of claim 1, further comprising, before the measuring of the first resistance:
continuously heating the semiconductor device using an external heating device before the transistor operates;
measuring a temperature value and a resistance value of the resistor unit at predetermined intervals while the semiconductor device is continuously heated; and
estimating a temperature of the active region based on a plurality of temperature values and a plurality of resistance values of the resistor unit while the transistor is operating.

7. The method of claim 6, wherein the estimating of the temperature of the active region includes:
calculating each of a plurality of temperature estimation values for the active region by adding an offset to each of the plurality of temperature values;
obtaining a relationship between the resistance value of the resistor unit and the temperature estimation value for the active region based on the plurality of resistance values and the plurality of temperature estimation values; and
estimating the temperature of the active region using the relationship while the transistor is operating,
wherein the offset is determined according to a distance between the resistor unit and the active region.

8. An apparatus for evaluating the degree of degradation of an active region of a transistor, the apparatus comprising:
a heating unit configured to heat a semiconductor device;
a measuring unit configured to measure a resistance value of a resistor unit that receives heat generated in an active region of a transistor disposed on the semiconductor device;
a memory configured to store at least one instruction; and
a processor connected to the heating unit, the measuring unit, and the memory to transmit and receive electrical signals and configured to execute the at least one instruction,
wherein the measuring unit measures a first resistance of the resistor unit, measures a second resistance of the resistor unit after the semiconductor device is heated by the heating unit, and repeatedly performs the measuring of the first resistance and the second resistance after a predetermined period of time has elapsed, and
the processor evaluates the degree of degradation of the active region based on a plurality of measured first resistances and a plurality of measured second resistances.

9. The apparatus of claim 8, wherein the measuring of the first resistance by the measuring unit, the heating of the semiconductor device by the heating unit, the measuring of the second resistance by the resistor unit, and the evaluating of the degree of degradation of the active region by the processor are performed while the transistor is operating.

10. The apparatus of claim 9, wherein the processor obtains a first resistance change rate before the predetermined period of time has elapsed, obtains a second resistance change rate after the predetermined period of time has elapsed, and compares a value obtained by dividing the second resistance change rate by the first resistance change rate with a predetermined threshold value.

11. The apparatus of claim 10, wherein:
the first resistance change rate is a value obtained by dividing a difference between the first resistance and the second resistance measured before the predetermined period of time has elapsed by first power used to heat the semiconductor; and
the second resistance change rate is a value obtained by dividing a difference between the first resistance and the second resistance measured after the predetermined period of time has elapsed by second power used to heat the semiconductor.

12. The apparatus of claim 11, wherein:
the heating unit includes an AC signal generating unit;
the AC signal generating unit applies an AC signal to a gate electrode of the transistor to heat the active region; and
a magnitude of a voltage of the AC signal is smaller than a magnitude of a threshold voltage that operates the transistor.

13. The apparatus of claim 8, wherein:
the processor continuously heats the semiconductor device using an external heating device before the transistor operates;
the measuring unit measures a temperature value and a resistance value of the resistor unit at predetermined intervals while the semiconductor device is continuously heated; and
the processor estimates a temperature of the active region based on a plurality of temperature values and a plurality of resistance values of the resistor unit while the transistor is operating.

14. The apparatus of claim 13, wherein:
the processor calculates each of a plurality of temperature estimation values for the active region by adding an offset to each of the plurality of temperature values,
obtains a relationship between the resistance value of the resistor unit and the temperature estimation value for the active region based on the plurality of resistance values and the plurality of temperature estimation values, and
estimates the temperature of the active region using the relationship while the transistor is operating; and
wherein the offset is determined according to a distance between the resistor unit and the active region.
